(19) United States
(12) Patent Application Publication
(10) Pub. No.: US 2025/0301878 A1
(43) Pub. Date: Sep. 25, 2025

(54) DISPLAY PANEL, ELECTRONIC DEVICE AND DISPLAY PANEL MANUFACTURING METHOD

(71) Applicants: Chengdu BOE Optoelectronics Technology Co., Ltd., Chengdu, Sichuan (CN); BOE Technology Group Co., Ltd., Beijing (CN)

(72) Inventors: Jingli YANG, Beijing (CN); Shuang FENG, Beijing (CN); Xin DENG, Beijing (CN); Yunpeng ZHANG, Beijing (CN); Yangzhong JING, Beijing (CN)

(21) Appl. No.: 18/839,845

(22) PCT Filed: Sep. 27, 2023
(86) PCT No.: PCT/CN2023/122086

§ 371 Date: Aug. 20, 2024

(30) Foreign Application Priority Data
Nov. 30, 2022 (CN) 202211528786.5

(51) Int. Cl. H10K 59/80; H10K 59/12; H10K 59/122; H10K 71/60

(52) U.S. Cl. CPC H10K 59/80515; H10K 59/1201; H10K 59/122; H10K 71/60

(57) ABSTRACT

The present application relates to a display panel, an electronic device and a display panel manufacturing method. The display panel includes a planarization layer, a sub-anode layer, a pixel define layer, an electroluminescent layer and a cathode layer. The sub-anode layer is configured to control light emission conditions of sub-pixels, and is above the planarization layer. The sub-anode layer has a plurality of separate sub-anodes. The sub-anode has a via hole penetrating therethrough. In the above structure, water vapor can be evaporated outwards through via holes on the sub anodes, so as to avoid the water vapor from being blocked between the planarization layer and the sub anode layer, and further avoid the situation existing in the sub anode layer in which the water vapor rises upwards and forms a protrusion and/or an opening. With the above configuration, it is beneficial to ensure the display effect of the display panel.

### TECHNICAL FIELD

The present application relates to the field of display technology, and in particular, to a display panel, an electronic device and a method of manufacturing the display panel.

### BACKGROUND

With the advancement of technology, display screens with a larger display panel are increasingly widely applied, for example, exhibition display screens that can be applied outside shopping malls, which may be used for advertisement display. The larger the area of this type of exhibition display screens is, the larger the area of their corresponding pixels is. In this case, when the pixels emit light, black dots in different degrees may appear thereon, such that incomplete light emission occurs, affecting the overall display effect.

### SUMMARY

The present application provides a display panel, an electronic device and a method of manufacturing the display panel, which can improve the display effect of the display panel.

According to a first aspect of the embodiments of the present application, there is provided a display panel, including: a planarization layer; a sub-anode layer, configured to control light emission conditions of sub-pixels, and above the planarization layer, where the sub-anode layer has a plurality of separate sub-anodes, and sub-anode has a via hole penetrating therethrough; a pixel define layer, on the sub-anode layer and away from the planarization layer, where the pixel define layer has a plurality of openings, and the openings expose at least a part of the sub-anodes; an electroluminescent layer, on the pixel define layer and away from the sub-anode layer; a cathode layer, on the electroluminescent layer and away from the sub-anode layer.

In some embodiments, an orthographic projection of the via hole onto the planarization layer is in an orthographic projection of each of the openings of the pixel define layer onto the planarization layer.

In some embodiments, the display panel further includes: a filling member, where a partial structure of the filling member enters the via hole, and is in contact with the planarization layer below the anode layer.

In some embodiments, a material of the filling member is the same as a material of the pixel define layer, and both are made of an organic material; water vapor produced in the planarization layer is volatilized outwards through the filling member; or a material of the filling member is the same as a material of the sub-anodes.

In some embodiments, the partial structure of the filling member is at an end of the sub-anode away from the planarization layer; or a plane where an end surface of the filling member away from the planarization layer is located coincides with a surface of the sub-anode away from the planarization layer.

In some embodiments, there are a plurality of via holes, and the plurality of via holes are respectively disposed in each of the sub-anodes.

In some embodiments, an area of the via hole is greater than or equal to 3 square microns and less than or equal to 800 square microns; and/or a ratio of the area of the via hole to an area of the sub-anode is greater than or equal to 5% and less than or equal to 15%; and/or a shape of the via hole includes at least one of following shapes: circular, polygonal, or oval.

In some embodiments, the sub-anode includes a plurality of sub-anode units and one or more connecting units, the plurality of sub-anode units are arranged at an interval, and the plurality of sub-anode units are electrically connected through the one or more connecting units; an interval region between the plurality of sub-anode units is used as the via hole.

In some embodiments, a ratio of a distance between adjacent sub-anode units to a size of the sub-anode unit is greater than or equal to 0.2 and less than or equal to 1; and/or an area of the sub-anode unit is less than or equal to 10000 square microns.

In some embodiments, there are a plurality of sub-anodes, and the plurality of sub-anodes are insulated from each other.

According to a second aspect of the embodiments of the present application, there is provided an electronic device, including: the display panel as described above.

According to a third aspect of the embodiments of the present application, there is provided a method of manufacturing a display panel, where the method is used to manufacture the display panel as described above, and includes: manufacturing a planarization layer; evaporating water vapor in the planarization layer by high-temperature heating; manufacturing sub-anodes on a surface of the planarization layer; forming one or more via holes on the sub-anodes; manufacturing a pixel define layer and a pixel support layer on the sub-anodes and the planarization layer; evaporating water vapor in the pixel define layer, the pixel support layer and the planarization layer by high-temperature heating, and volatilizing the water vapor in the planarization layer outwards through the one or more via holes.

In some embodiments, the manufacturing method further includes: forming a filling layer on the sub-anodes, where a partial structure of the filling layer enters the one or more via holes and forms one or more filling members.

According to the display panel, the electronic device and the method of manufacturing the display panel provided in the present application, in a process of manufacturing the display panel with the above structure, after the planarization layer and the sub-anode layer are manufactured, the pixel define layer and a pixel support layer need to be manufactured; in a process of manufacturing the pixel define layer and the pixel support layer, a high-temperature heating process is need; water vapor will be produced in the planarization layer during the high-temperature heating process. The water vapor may be evaporated outwards through the one or more via holes on the sub-anodes, so as to avoid the water vapor from being blocked between the planarization layer and the sub-anode layer, and further avoid the situation existing in the sub-anodes in which the water vapor rises upwards and forms a protrusion and/or an opening and a cavity. With the above configuration, it is beneficial to ensure the display effect of the display panel.

It should be understood that the above general description and the following detailed description are only exemplary and explanatory and are not restrictive of the present application.

### BRIEF DESCRIPTION OF DRAWINGS

The accompanying drawings, which are incorporated in and constitute a part of this specification, illustrate examples consistent with the present application and, together with the description, serve to explain the principle of the application.

FIG. 1 is a structural schematic diagram showing a display panel according to an embodiment of the present application.

FIG. 2 is a structural schematic diagram showing another display panel according to an embodiment of the present application.

FIG. 3 is a structural schematic diagram showing sub-pixels in a display panel according to an embodiment of the present application.

FIG. 4 is another structural schematic diagram showing sub-pixels in a display panel according to an embodiment of the present application.

FIG. 5 is another structural schematic diagram showing sub-pixels in a display panel according to an embodiment of the present application.

FIG. 6 is another structural schematic diagram showing sub-pixels in a display panel according to an embodiment of the present application.

FIG. 7 is another structural schematic diagram showing sub-pixels in a display panel according to an embodiment of the present application.

FIG. 8 is another structural schematic diagram showing sub-pixels in a display panel according to an embodiment of the present application.

FIG. 9 is a schematic flowchart showing a process of manufacturing a display panel according to an embodiment of the present application.

### DESCRIPTION OF REFERENCE SIGNS

| | | |
|---|---|---|
| Display panel 10 | Sub-pixel 11 | First sub-pixel 12 |
| Second sub-pixel 13 | Third sub-pixel 14 | Base portion 100 |
| Functional portion 200 | PI layer 110 | Barrier layer 120 |
| Gate insulator layer 210 | Gate signal line 220 | Poly layer 230 |
| Interlayer dielectric layer 240 | PVX layer 250 | Signal data line layer 260 |
| Planarization layer 270 | First planarization layer 271 | Second planarization layer 272 |
| Pixel define layer 280 | Opening 281 | Pixel support layer 290 |
| Sub-anode layer 300 | Sub-anode 301 | Via hole 310 |
| Sub-anode unit 320 | Connecting unit 330 | Electroluminescent layer 400 |
| Cathode layer 500 | Chemical vapor deposition layer 600 | Filling member 700 |

### DETAILED DESCRIPTION

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present application. Rather, they are merely examples of apparatuses and methods consistent with some aspects of the present application as detailed in the appended claims.

The terms used in the present application are for the purpose of describing particular embodiments only, and are not intended to limit the present application. Unless otherwise defined, technical or scientific terms used in the present application should have ordinary meaning as understood by one of ordinary skill in the art to which the present application belongs. Similar words such as “one,” “a” or “an” used in the specification and claims of the present application do not represent a quantity limit, but represent that there is at least one. “Plurality,” “multiple” or “several” means two or more. Similar words such as “including” or “comprising” mean that an element or an item appearing before “including” or “comprising” covers elements or items and their equivalents listed after “including” or “comprising”, without excluding other elements or items. Similar words such as “connect” or “connected with each other” are not limited to physical or mechanical connections, and may include electrical connections, whether direct or indirect. Similar words such as “upper” and/or “lower” are only for convenience of description, and are not limited to one position or one spatial orientation. Terms determined by “a/an”, “the” and “said” in their singular forms in the specification and the appended claims of the present application are also intended to include plural forms unless clearly indicated otherwise in the context. It should also be understood that the term “and/or” as used herein refers to and includes any or all possible combinations of one or more associated listed items.

The present application provides a display panel, an electronic device and a method of manufacturing the display panel. The display panel includes a planarization layer, a sub-anode layer, a pixel define layer, an electroluminescent layer and a cathode layer. The sub-anode layer is configured to control light emission conditions of sub-pixels, and is above the planarization layer. The sub-anode layer has a plurality of separate sub-anodes. Each sub-anode has a via hole penetrating therethrough. The pixel define layer is on the sub-anode layer and away from the planarization layer. The pixel define layer has a plurality of openings. The openings expose at least a part of the sub-anodes. The electroluminescent layer is on the pixel define layer and away from the sub-anode layer. The cathode layer is on the electroluminescent layer and away from the sub-anode layer.

According to the display panel, the electronic device and the method of manufacturing the display panel provided in the present application, in a process of manufacturing the display panel with the above structure, after the planarization layer and the sub-anode layer are manufactured, the pixel define layer and a pixel support layer need to be manufactured; in a process of manufacturing the pixel define layer and the pixel support layer, a high-temperature heating process is need; water vapor will be produced in the planarization layer during the high-temperature heating process. The water vapor may be evaporated outwards through one or more via holes on the sub-anodes, so as to ensure the display effect of the display panel.

The display panel in the present application is an OLED display panel, which may be applied to electronic devices with a display function, for example, exhibition display screens or televisions, and the display panel has a larger size. The display panel may serve as a display panel of the electronic devices with a display function, for example, exhibition display screens or televisions.

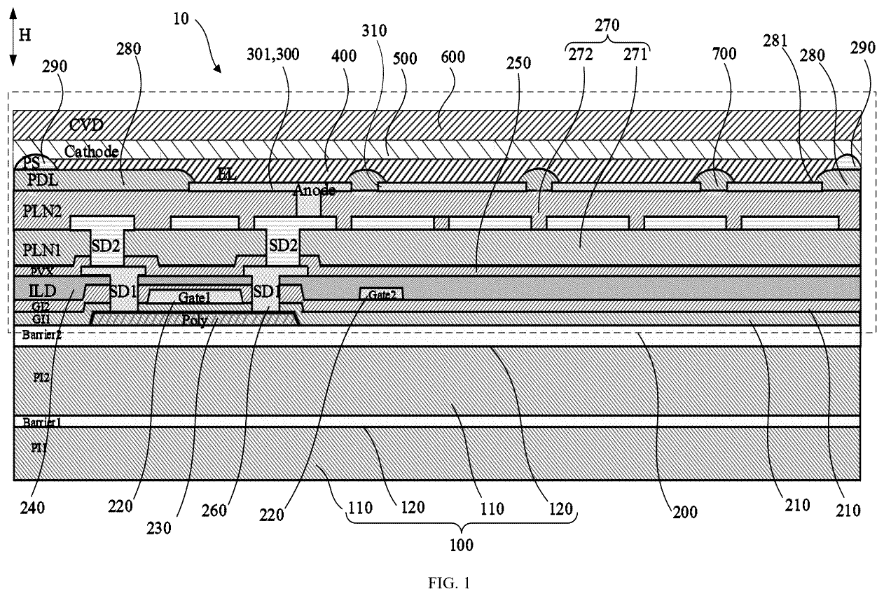

A display panel 10 provided in the present application will be described in detail below with reference to FIG. 1 to FIG. 8.

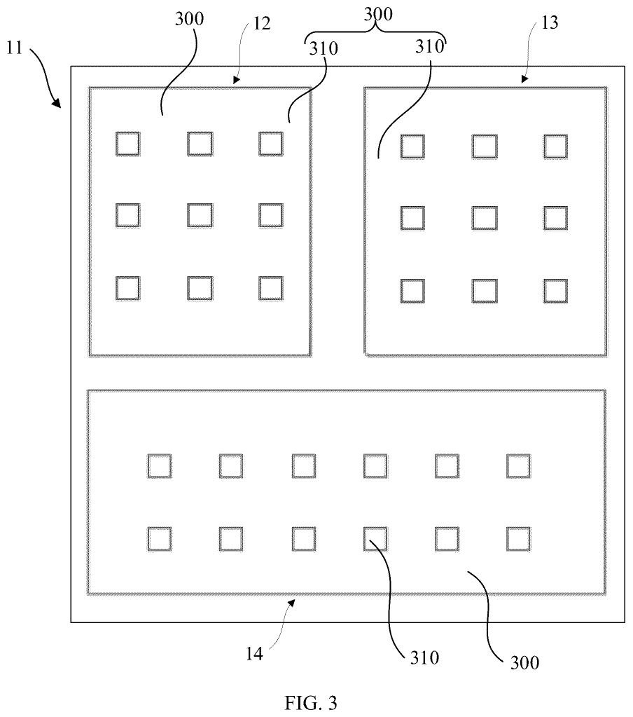

As shown in FIG. 1 and FIG. 3, the display panel 10 has a plurality of pixels, each pixel includes a plurality of sub-pixels 11, and each sub-pixel 11 includes a first sub-pixel 12 for generating red light, a second sub-pixel 13 for generating blue light, and a third sub-pixel 14 for generating green light. Each pixel includes one first sub-pixel 12, one second sub-pixel 13, and one third sub-pixel 14. The first sub-pixel 12, one second sub-pixel 13, and one third sub-pixel 14 each includes a base portion 100 and a functional portion 200. The first sub-pixel 12, one second sub-pixel 13, and one third sub-pixel 14 may share the base portion 100 and partial film layer structure in the functional portion 200.

Specifically, the base portion 100 includes a PI layer (Polyimide layer) 110 and a barrier layer 120. There are two barrier layers 120 and two PI layers 110. The barrier layers 120 and the PI layers 110 are alternately arranged along a thickness direction. The functional portion 200 includes a gate insulator (GI) layer 210, a gate signal line 220, a Poly layer 230, an interlayer dielectric (ILD) layer 240, a Passivation (PVX) layer 250, a data wiring (signal data line, SD) layer 260, a planarization (PLN) layer 270, a pixel define layer (PDL) 280, a pixel support (PS) layer 290, a sub-anode layer 300, an organic functional layer (electroluminescent layer, EL), a cathode layer 500, and an encapsulation layer (Chemical Vapor Deposition, CVD) 600. The sub-anode layer is configured to control light emission conditions of pixels, and is above the planarization layer 270. Specifically, the sub-anode layer 300 has a plurality of separate sub-anodes 301. The sub-anodes 301 of each sub-pixel 11 are independently disposed. In other words, there are a plurality of sub-anodes 301 in the display panel 10, the plurality of sub-anodes 301 are insulated from each other, and a sub-anode 301 and the sub-pixel 11 are disposed in one-to-one correspondence. Voltages applied to the sub-anodes 301 and the cathode layer 500 are controlled through the gate signal line 220 and the signal data line layer 260, and thereby a light emission condition of the electroluminescent layer 400 in each sub-pixel 11 is controlled. The pixel define layer 280 is on the sub-anode layer 300 and away from the planarization layer 270, and the pixel define layer 280 has a plurality of openings 281. The openings 281 expose at least a part of the sub-anodes 301. The electroluminescent layer 400 includes an electron transport layer, a light emitting material layer, and a hole transport layer, and is on the pixel define layer 280 and away from the sub-anode layer 300. The cathode layer 500 is on the electroluminescent layer 400 and away from the sub-anode layer 300. In addition, there are two gate insulator layers 210, two gate signal lines 220, two signal data line layers 260 and two planarization layers 270.

For the planarization layer 270 and the manufacturing process on the planarization layer 270, the planarization layer 270 is usually first manufactured, and then the pixel define layer 280 is manufactured above the planarization layer 270. At this time, the pixel define layer 280 has a plurality of openings 281. Then, the sub-anode layer 300 is manufactured on the planarization layer 270, and a coverage region of the sub-anode layer 300 is limited by the pixel define layer 280. Specifically, the sub-anode layer 300 enters the interior of the openings 281, and forms the sub-anodes 301, such that the openings 281 expose at least a part of the sub-anodes 301. Then, the pixel support layer 290 is manufactured on the pixel define layer 280, and thereafter, the electroluminescent layer 400 is manufactured within a range limited by the pixel define layer 280 and the pixel support layer 290. Finally, the cathode layer 500 and the chemical vapor deposition layer 600 are manufactured. Of course, in other embodiments, the manufacturing process may be slightly different.

In the process of manufacturing the planarization layer 270, the high-temperature heating process is needed. During the high-temperature heating process, water vapor in the planarization layer 270 may be evaporated, and after the water vapor is evaporated, the sub-anode layer 300 is manufactured thereon. Then, after the pixel define layer 280 and the pixel support layer 290 are manufactured, the high-temperature heating process needs to be performed on the pixel define layer 280 and the pixel support layer 290. In this process, the entire structure formed in the preceding steps (including the planarization layer 270) needs to be heated at a high temperature. At this time, a part of residual water vapor still remains in the planarization layer 270 below the sub-anode layer 300, and will be evaporated upwards during this step. At this time, the water vapor evaporated from the planarization layer 270 is blocked between the planarization layer 270 and the sub-anode layer 300.

It should be noted that, in the embodiments, there are two planarization layers 270, which are respectively a first planarization layer 271 and a second planarization layer 272. The second planarization layer 272 is above the first planarization layer 271, and both are made of an organic material. Water vapor produced in the first planarization layer 271 during the above steps enters the second planarization layer 272, and continues to move upwards from the second planarization layer 272 to a gap between the second planarization layer 272 and the sub-anode layer 300.

From a large number of experiments, inventors found that, when an area of the display panel 10 is smaller, areas of corresponding pixel and sub-pixel 11 in the display panel are smaller, for example, the display panel 10 in a mobile phone, especially, the display panel 10 with a high PPI. For this type of display panel 10, since the area of a sub-pixel 11 is smaller, there is usually one sub-anode layer 300 corresponding to one sub-pixel 11, and an area of the corresponding sub-anode layer 300 is smaller. At this time, during the high-temperature heating process after the sub-anode layer 300 is formed, the planarization layer 270 below the sub-anode layer 300 still has water vapor evaporated upwards into a gap between the planarization layer 270 and the sub-anode layer 300. Since the area of the sub-anode layer 300 is smaller, this part of water vapor will move to an edge of the sub-anode layer 300 and escape outwards. At this time, the sub-anode layer 300 will not be damaged. However, when the area of the display panel 10 is larger, the areas of corresponding pixel and sub-pixel 11 in the display panel are larger, for example, a large display panel applied to shopping malls for displaying pictures or video advertisements. There is usually one sub-anode layer 300 corresponding to one sub-pixel 11, and at this time, the area of the sub-anode layer 300 is larger. In this case, during the high-temperature heating process after the sub-anode layer 300 is formed, the planarization layer 270 below the sub-anode layer 300 still has water vapor evaporated upwards into a gap between the planarization layer 270 and the sub-anode layer 300. However, since the area of the sub-anode layer 300 is larger, the water vapor does not easily move to the edge of the sub-anode layer 300, and cannot escape outwards. At this time, the water vapor blocked between the planarization layer 270 and the sub-anode layer 300 applies an upward pushing force to a part of the sub-anode layer 300, such that an upward protrusion is formed on the sub-anode layer 300. After the protrusion is formed, a film layer above the sub-anode layer 300 is formed with a corresponding protrusion structure. At the same time, once a protruding degree of the protrusion is too large, the film layer breaks to form an opening, and especially, the sub-anode layer 300 breaks to form an opening. In this case, the water vapor blocked between the planarization layer 270 and the sub-anode layer 300 enters the electroluminescent layer 400 above the sub-anode layer 300, thereby affecting a light emitting material of the electroluminescent layer 400. Both phenomena may affect the light emission of the electroluminescent layer 400, resulting in that black dots in different degrees appear on the display panel 10, and further incomplete light emission occurs, which affects the overall display effect.

In view of the above problems, the inventors made the following improvements: the sub-anode layer 300 are provided with one or more via holes 310 penetrating therethrough.

In the process of manufacturing the display panel 10 with the above structure, when the pixel define layer 280 and the pixel support layer 290 are heated at a high temperature, water vapor is produced in the formed planarization layer 270 under the high-temperature heating. The water vapor can be evaporated outwards through the via holes 310 on the sub-anodes 301, so as to avoid the water vapor from being blocked between the planarization layer 270 and the sub-anodes 301, and further avoid the situation existing in the sub-anodes 301 in which the water vapor blocked between the planarization layer 270 and the sub-anode layer 300 rises upwards, and forms a protrusion and/or an opening. With the above configuration, incomplete light emission, such as black dots appearing on the display panel 10, can be avoided, which is beneficial to ensure the display effect of the display panel 10.

In some embodiments, an orthographic projection of the via hole 310 onto the planarization layer 270 is in the orthographic projection of the opening 281 of the pixel define layer 280 onto the planarization layer 270. In the above structure, the water vapor can overflow outwards from the interior of the sub-anodes 301 through the via holes 310, and move away from the pixel define layer 280. With the above configuration, water vapor blockage can be further avoided.

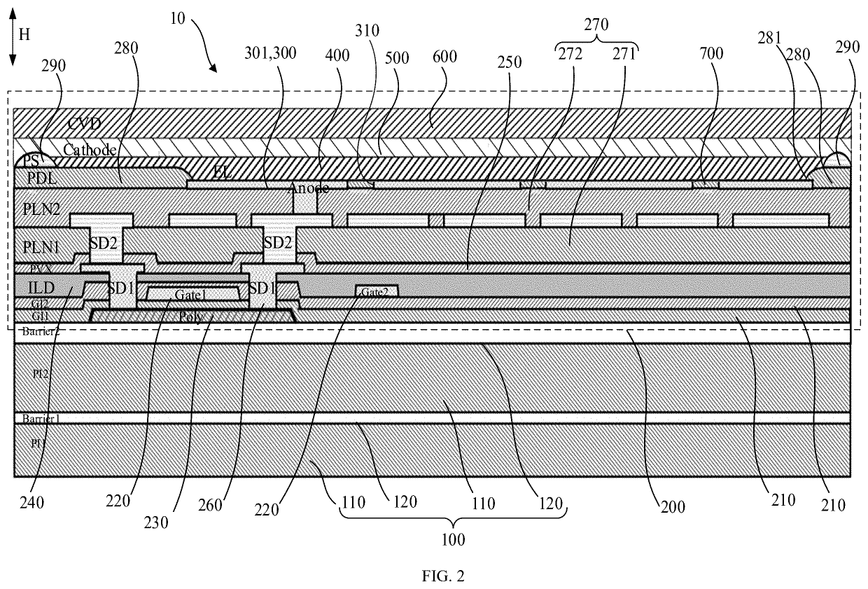

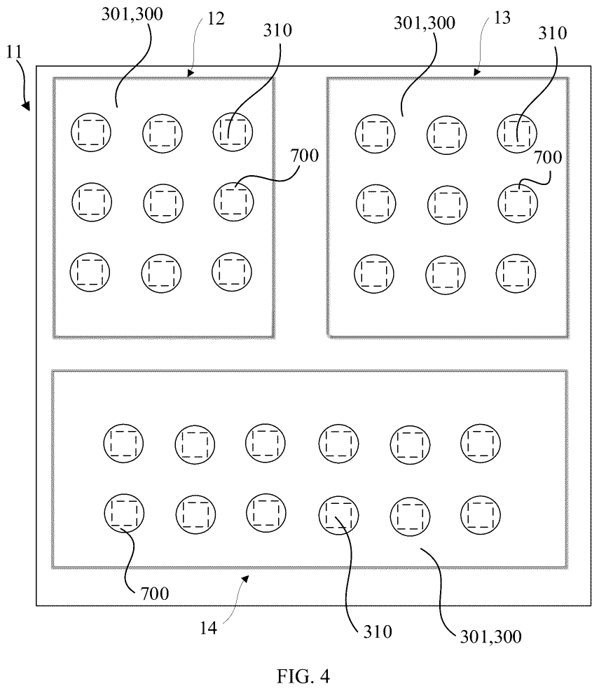

As shown in FIG. 1, FIG. 2 and FIG. 4, the display panel 10 further includes a filling member 700. At least a partial structure of the filling member 700 enters the via hole 310 to cover the via hole 310, and is in contact with the planarization layer 270 below the anode layer. By forming the filling member 700 in the via hole 310, the electroluminescent layer 400 can be avoided from falling into the via hole 310, and thereby the structure of the electroluminescent layer 400 can be avoided from being scratched by a wall surface forming the via hole 310. With the above configuration, the stability of the structure of the electroluminescent layer 400 is ensured, and thereby the stability of light emission of the display panel 10 is ensured. In the embodiments, at least the partial structure of the filling member 700 is at an end of the sub-anode 301 away from the planarization layer 270. With the above configuration, it can be ensured that the filling member 700 covers the via hole 310, and the electroluminescent layer 400 cannot enter the via hole 310, and cannot be in contact with the wall surface forming the via hole 310.

Of course, in other embodiments, as shown in FIG. 2, a plane where an end surface of the filling member 700 away from the planarization layer 270 is located is used as a first plane, and a surface of the sub-anode 301 away from the planarization layer 270 is used as a second plane. The first plane coincides with the second plane. In other words, a distance from an end of the filling member 700 away from the planarization layer 270 to the planarization layer 270 is the same as a distance from an end of the sub-anode 301 away from the planarization layer 270 to the planarization layer 270. At this time, a height of the filling member 700 is the same as a height of the sub-anode 301, such that there is no step difference between their surfaces away from the planarization layer 270, which avoids the risks of a step difference and a breaking existing on the electroluminescent layer 400. With the above configuration, the stability of the display effect is ensured, and meanwhile, the service life of the display panel 10 is prolonged.

At the same time, a material of the filling member 700 may be the same as a material of the pixel define layer 280, and both may be made of an organic material. In this case, the water vapor produced in the planarization layer 270 can be volatilized outwards through the filling member 700, thereby avoiding the water vapor from being blocked in the film layer. The high-temperature heating process after the pixel define layer 280 and the pixel support layer 290 are manufactured needs to be performed before the electroluminescent layer 400 is manufactured, so as to avoid the water vapor from being blocked by the electroluminescent layer 400, and further avoid the water vapor from entering a light emitting layer. At this time, the filling member 700 may be formed synchronously with the pixel define layer 280. Of course, in other embodiments, the material of the filling member 700 may be the same as a material of the sub-anode 301. In this case, the pixel define layer 280 and the pixel support layer 290 need to be first formed, and the high-temperature heating process is performed after the pixel define layer 280 and the pixel support layer 290 are manufactured, such that the water vapor can first overflow outwards through the via holes 310, and then the filling member 700 is formed.

It should be noted that, when the material of the filling member 700 is the same as the material of the pixel define layer 280, they may be formed through the same step. Of course, in other embodiments, two film layers of the filling member 700 and the pixel define layer 280 may be formed through different steps.

In the embodiments shown in FIGS. 3-7, there are a plurality of via holes 310, and the plurality of via holes 310 are in the sub-anodes 301.

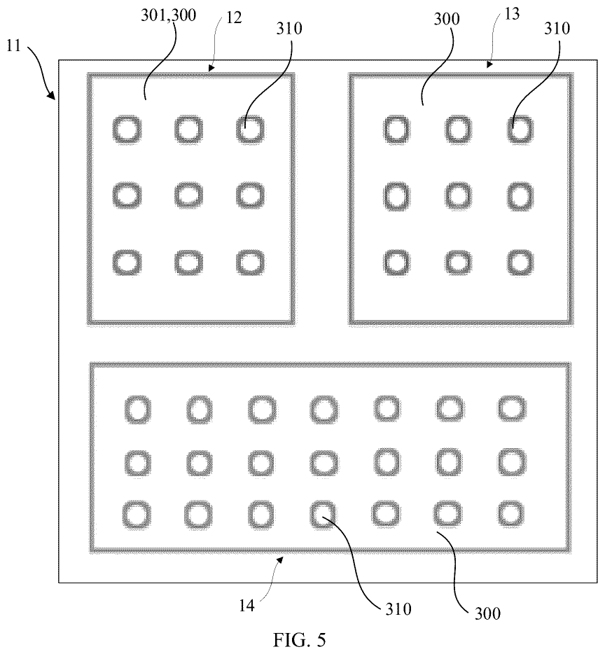

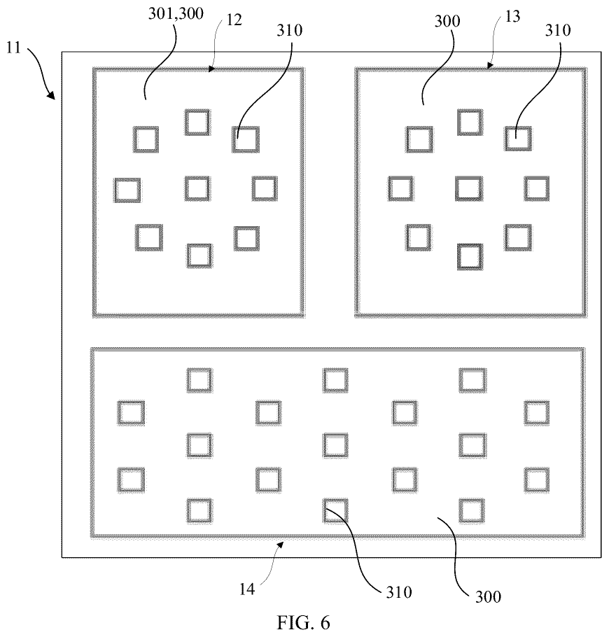

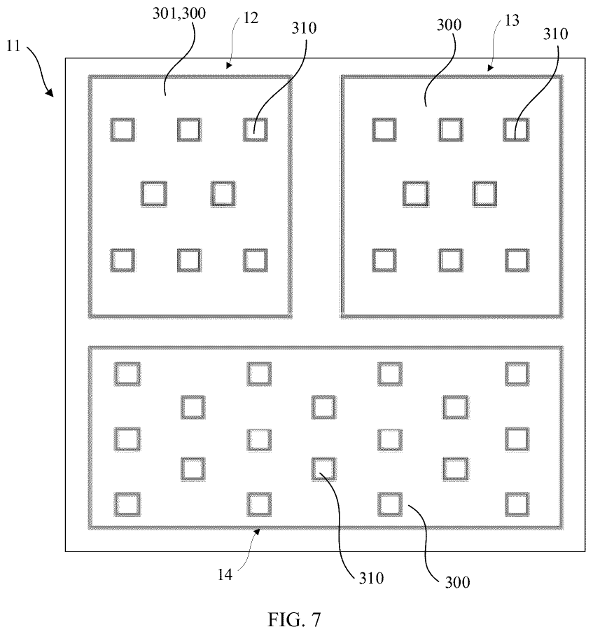

A shape of the via hole 310 may be circular (as shown in FIG. 5), and the shape of the via hole 310 may be rectangular (as shown in FIGS. 3, 4, 6 and 7). The via holes 310 in FIG. 3 and FIG. 4 are evenly aligned and arranged in rows and columns. The via holes 310 in FIG. 6 are arranged in a surrounding shape. The via holes 310 in FIG. 7 are alternately arranged in rows and columns. Of course, the shape of the via hole 310 may be of other polygonal structures, oval structures or other special-shaped structures.

Further, the inventors conducted corresponding research on a size of the via hole 310. The inventors found that, when an area of the via hole 310 is too large, an area of the sub-anode 301 is limited, resulting in that the uniformity of voltages applied to the electroluminescent layer 400 is limited, and further the display effect is affected. When the area of the via hole 310 is too small, it is difficult for the water vapor to overflow outwards from the via hole 310, such that it is difficult to avoid the appearance of protrusions and/or openings on the sub-anodes 301, and further the display effect is affected. Through a large number of experiments, the inventors verified that, when the area of the via hole 310 is greater than or equal to 3 square microns and less than or equal to 800 square microns, the above problems can be well balanced to achieve a better display effect. Of course, in a specific embodiment, the area of the via hole 310 may be 100 square microns, 200 square microns, 300 square microns, 500 square microns, or the like. In the embodiment shown in FIG. 3, the via hole 310 is a rectangle with an edge length of 23 microns.

At the same time, the inventors found that, when a ratio of an area of the via holes 310 to the area of the sub-anode 301 is too large, the area of the sub-anode 301 is likewise limited, resulting in that the uniformity of voltages applied to the electroluminescent layer 400 is limited, and further the display effect is affected. When the ratio of the area of the via holes 310 to the area of the sub-anode 301 is too small, it is difficult for water vapor to overflow outwards from the via holes 310, such that it is difficult to avoid the appearance of protrusions and/or openings on the sub-anodes 301, and further the display effect is affected. Through a large number of experiments, the inventors verified that, when the ratio of the area of the via hole 310 to the area of the sub-anode 301 is greater than or equal to 5% and less than or equal to 15%, the above problems can be well balanced to achieve a better display effect.

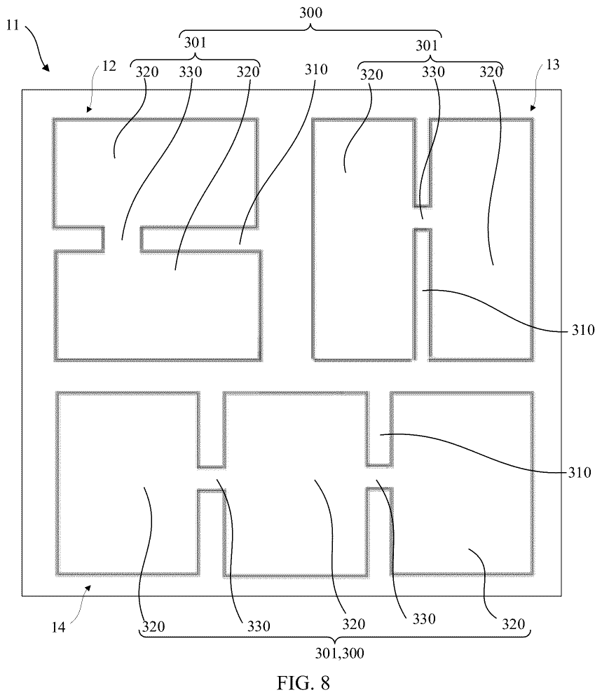

In other embodiments, the via hole 310 on the sub-anode layer 300 may be of a structure not in the sub-anode 301. Specifically, as shown in FIG. 8, each sub-anode 301 includes a plurality of sub-anode units 320 and one or more connecting units 330. The plurality of sub-anode units 320 are arranged at an interval, and the plurality of sub-anode units 320 are electrically connected through the one or more connecting units 330. An interval region between the plurality of sub-anode units 320 is used as the via hole 310. At this time, a part of water vapor can directly overflow outwards from the via hole 310. Although another part of water vapor is blocked between the planarization layer 270 and the sub-anode units 320, since an area of the sub-anode unit 320 is relatively small, this part of water vapor can still easily move to a gap position between the plurality of sub-anode units, that is, a position of the via hole 310, and overflow outwards, which avoids the appearance of protrusions and/or openings on the sub-anodes 301, and ensures the display effect.

In some embodiments, a ratio of a distance between adjacent sub-anode units 320 to a size of the sub-anode unit is greater than or equal to 0.2 and less than or equal to 1. It should be noted that the size of the sub-anode units 320 referred to herein is a transverse size, or a longitudinal size, or a diameter of the sub-anode units 320. Through the limitation of the above range, it is ensured that the sub-anode units 320 have a sufficient area to ensure that uniform voltages can be applied to the electroluminescent layer 400, thereby ensuring the display effect. Meanwhile, it is ensured that the via hole 310 has a sufficient size to ensure that water vapor can successfully overflow.

Meanwhile, the area of the sub-anode unit 320 needs to be ensured to be less than or equal to 10000 square microns, thereby avoiding the problem that, since the area of the sub-anode unit 320 is too large, the water vapor cannot move to edges of the sub-anode units 320 and cannot overflow outwards from the via hole 310, and further ensuring the display effect.

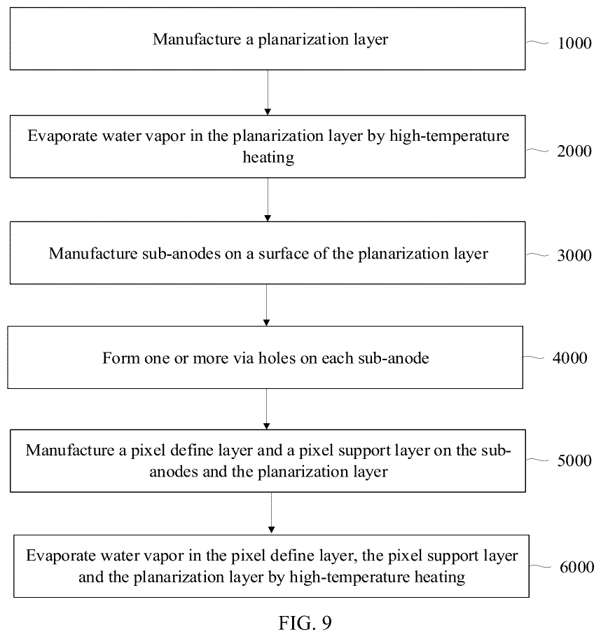

As shown in FIG. 9, the present application further discloses a method of manufacturing the display panel 10. The manufacturing method is used for manufacturing at least partial structures in the display panel 10. The manufacturing method includes step 1000 to step 7000.

At step 1000, a planarization layer 270 is manufactured.

At step 2000, water vapor in the planarization layer 270 is evaporated by high-temperature heating.

At step 3000, sub-anodes 301 are manufactured on a surface of the planarization layer 270. Specifically, a sub-anode layer 300 needs to be first formed by depositing on the planarization layer 270, and then a plurality of separate sub-anodes 301 are formed through an etching process.

At step 4000, one or more via holes 310 are formed on each sub-anode 301.

At step 5000, a pixel define layer 280 and a pixel support layer 290 are manufactured on the sub-anodes 301 and the planarization layer 270. Specifically, in the process of manufacturing the pixel define layer 280, after an organic material is deposited, openings 281 need to be formed through an etching process, such that at least a partial structure of the sub-anodes 301 is exposed through the openings 281.

At step 6000, water vapor in the pixel define layer 280, the pixel support layer 290 and the planarization layer 270 is evaporated by high-temperature heating, and the water vapor in the planarization layer 270 is volatilized outwards through the one or more via holes 310.

In the display panel 10 manufactured through the above steps, the water vapor produced in the planarization layer 270 can overflow outwards through the via holes 310, thereby avoiding the appearance of protrusions and/or openings on the sub-anodes 301, and ensuring the display effect.

In some embodiments, the manufacturing method further includes: at step 7000, a filling layer is formed on the sub-anodes 301, a partial structure of the filling layer enters the one or more via holes 310, and forms one or more filling members 700.

By forming the one or more filling members 700 in the one or more via holes 310, the electroluminescent layer 400 can be avoided from falling into the one or more via holes 310, thereby avoiding the structure of the electroluminescent layer 400 from being scratched by wall surfaces forming the via holes 310. With the above configuration, the stability of the structure of the electroluminescent layer 400 is ensured, and the stability of light emission of the display panel 10 is ensured.

It should be noted that step 7000, that is, the step of forming the filling members 700, may be performed after step 6000 is performed, or be performed synchronously with step 5000. When step 7000 and step 5000 are performed synchronously, the filling layer and the pixel define layer 280 may be formed synchronously. For example, when a material of the filling members 700 is the same as a material of the pixel define layer 280, step 7000 and step 5000 are performed synchronously, that is, the filling layer and the pixel define layer 280 may be formed synchronously. When step 6000 is performed subsequently, high temperature will cause water vapor in the filling members 700 to be evaporated from its interior toward a direction away from the sub-anodes 301. In addition, it should be noted that, in the process of actual operation, the pixel define layer 280 and the pixel support layer 290 are not manufactured in the same step. Generally, the pixel define layer 280 is first manufactured, and then the pixel support layer 290 is manufactured on the pixel define layer 280. When the material of the filling members 700 is the same as a material of the sub-anodes 301, step 5000 and step 6000 need to be first performed, and then step 7000 is performed. Specifically, the pixel define layer 280 and the pixel support layer 290 need to be formed, and the high-temperature heating process is performed after the pixel define layer 280 and the pixel support layer 290 are manufactured, such that water vapor can first overflow outwards through the via holes 310, and then the filling members 700 are formed. With the above configuration, the water vapor is avoided from being blocked by the filling members 700.

In the present application, the structure embodiments and the method embodiments may be complemented to each other without conflict.

In the present application, terms “first” and “second” are used only for descriptive purposes, and cannot be understood as indicating or implying relative importance. Terms “plurality”, “multiple” and “several” mean two or more, unless clearly defined otherwise.

Other embodiments of the present application will be readily apparent to those skilled in the art after considering the specification and the disclosure. The present application is intended to cover any variations, uses, or adaptations of the present application, which follow the general principle of the present application and include common knowledge or conventional technical means in the art that are not disclosed in the present application. The specification and examples are to be regarded as illustrative only. The true scope and spirit of the present application are pointed out by the following claims.

It is to be understood that the present application is not limited to the precise structures that have described and shown in the drawings, and various modifications and changes can be made without departing from the scope thereof. The scope of the application is to be limited only by the appended claims.

1. A display panel, comprising:
a planarization layer;
a sub-anode layer, configured to control light emission conditions of sub-pixels, and above the planarization layer, wherein the sub-anode layer has a plurality of separate sub-anodes, and the sub-anode has a via hole penetrating therethrough;
a pixel define layer, on the sub-anode layer and away from the planarization layer, wherein the pixel define layer has a plurality of openings, and the opening exposes at least a part of the sub-anode;
an electroluminescent layer, on the pixel define layer and away from the sub-anode layer;
a cathode layer, on the electroluminescent layer and away from the sub-anode layer.

2. The display panel according to claim 1, wherein an orthographic projection of the via hole onto the planarization layer is in an orthographic projection of the opening of the pixel define layer onto the planarization layer.

3. The display panel according to claim 1, further comprising: a filling member, wherein a partial structure of the filling member enters the via hole, and is in contact with the planarization layer below the anode layer.

4. The display panel according to claim 3, wherein a material of the filling member is the same as a material of the pixel define layer, and both are made of an organic material; water vapor produced in the planarization layer is volatilized outwards through the filling member.

5. The display panel according to claim 3, wherein the partial structure of the filling member is at an end of the sub-anode away from the planarization layer.

6. The display panel according to claim 1, wherein there are a plurality of via holes, and the plurality of via holes are respectively disposed in each of the sub-anodes.

7. The display panel according to claim 61, wherein an area of the via hole is greater than or equal to 3 square microns and less than or equal to 800 square microns.

8. The display panel according to claim 1, wherein the sub-anode comprises a plurality of sub-anode units and one or more connecting units, the plurality of sub-anode units are arranged at an interval, and the plurality of sub-anode units are electrically connected through the one or more connecting units;
an interval region between the plurality of sub-anode units is used as the via hole.

9. The display panel according to claim 8, wherein a ratio of a distance between adjacent sub-anode units to a size of the sub-anode unit is greater than or equal to 0.2 and less than or equal to 1.

10. The display panel according to claim 1, wherein the plurality of sub-anodes are insulated from each other.

11. An electronic device, comprising: the display panel according to claim 1.

12. A method of manufacturing a display panel, wherein the method is used to manufacture the display panel according to claim 1, and comprises:
manufacturing a planarization layer;
evaporating water vapor in the planarization layer by high-temperature heating;
manufacturing sub-anodes on a surface of the planarization layer;
forming one or more via holes on the sub-anodes;
manufacturing a pixel define layer and a pixel support layer on the sub-anodes and the planarization layer;
evaporating water vapor in the pixel define layer, the pixel support layer and the planarization layer by high-temperature heating, and volatilizing the water vapor in the planarization layer outwards through the one or more via holes.

13. The method according to claim 12, further comprising:
forming a filling layer on the sub-anodes, wherein a partial structure of the filling layer enters the one or more via holes and forms one or more filling members.

14. The display panel according to claim 3, wherein a material of the filling member is the same as a material of the sub-anodes.

15. The display panel according to claim 3, wherein a plane where an end surface of the filling member away from the planarization layer is located coincides with a surface of the sub-anode away from the planarization layer.

16. The display panel according to claim 1, wherein a ratio of the area of the via hole to an area of the sub-anode is greater than or equal to 5% and less than or equal to 15%.

17. The display panel according to claim 1, wherein a shape of the via hole comprises at least one of following shapes: circular, polygonal, or oval.

18. The display panel according to claim 8, wherein an area of the sub-anode unit is less than or equal to 10000 square microns.
